(19) United States
(12) Patent Application Publication
(10) Pub. No.: US 2007/0178391 A1
(43) Pub. Date: Aug. 2, 2007

(54) Mask having balance pattern and method of patterning photoresist using the same

(75) Inventors: Tae-Young Kim, Seoul (KR); Sang-Jin Kim, Suwon-si (KR); Cha-Won Koh, Yongin-si (KR); Sung-Gon Jung, Seoul (KR); Myoung-Ho Jung, Suwon-si (KR); Young-Mi Lee, Seoul (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/525,965

(22) Filed: Sep. 25, 2006

(30) Foreign Application Priority Data
Feb. 2, 2006 (KR) 2006-0010310

(51) Int. Cl. G03C 5/00; G03F 1/00; G03F 9/00

(52) U.S. Cl. 430/5; 430/394; 430/322; 430/22

(57) ABSTRACT

A method and mask having balance patterns for reducing and/or preventing chemical flare from occurring in a photoresist between a first mask region and a second mask region. Balance patterns formed on the mask may have a desired and/or predetermined pitch and may be regularly arranged. If the pitch of the balance patterns is equal to or smaller than a threshold value, the balance patterns may not allow the patterns to be transferred onto a photoresist. In addition, the photoresist corresponding to the balance patterns may be either completely removed or completely remain depending on the duty of the balance patterns.

### PRIORITY STATEMENT

This application claims the benefit of Korean Patent Application No. 2006-0010310, filed Feb. 2, 2006, the entire contents of which is incorporated herein by reference.

### BACKGROUND OF THE INVENTION

1. Field of the Invention

Example embodiments of the present invention relate to a photolithography process, and more particularly, to a mask including balance patterns used in a photolithography process.

2. Description of the Related Art

A photolithography process may be used in the fabrication of semiconductor devices to form patterns on a semiconductor substrate. The photolithography process may include a photoresist coating process, an alignment/exposure process, and a development process. In particular, the photolithography process may take advantage of a phenomenon, wherein the molecular structure of a photoresist changes when the photoresist is irradiated by light, thereby causing the solubility of an exposed portion of the photoresist to differ from that of a non-exposed portion of the photoresist.

A mask may be employed to selectively expose the photoresist and to transfer patterns. If an image of a substrate coated with chrome is transferred to the entire wafer, the substrate may be referred to as a mask. If the image of the substrate coated with chrome is transferred to a portion of the wafer, the substrate may be referred to as a reticle. However, the terms mask and reticle as of Feb. 2, 2006, the filing date of Korean Patent Application No. 2006-0010310 to which this application claims priority have not been strictly defined. Accordingly, the two kinds of substrates coated with chrome and/or MoSiON used as a semi-transmissive layer, may be collectively referred to as a mask. Hereinafter, it should be noted that the above-described two kinds of substrates coated with chrome are collectively referred to as a mask.

In addition, a chrome pattern formed on the substrate may be referred to as a mask pattern.

As a design rule indicating a feature size is reduced and pattern density increases, line width may vary and a pattern shape may tend to differ from a design layout due to a phenomenon referred to as flare phenomenon. Flare phenomenon may include both local flare and chemical flare, which are discussed below.

Local flare may occur due to aberration of an optical lens and/or unevenness of a surface of an optical lens. That is, if a dark field where dense patterns are disposed and a clear field where patterns are not formed are simultaneously exposed to light, an abnormal line width may be formed in a dark field pattern in close proximity to the clear field, at least in part due to light irradiated onto the clear field.

One conventional technique for coping with the above-described local flare phenomenon is to implement a halftone layer in a mask region corresponding to the clear field. The intensity of light transmitted through the halftone layer is significantly reduced as compared to the case when no halftone layer is present. Accordingly, the abnormal line width may be reduced and/or prevented in the pattern of the dark field in close proximity to the clear field.

Chemical flare generally occurs at a boundary between a region where patterns are dense and a region where patterns are not dense and/or not formed at all. That is, exposure causes acid to move in a region where exposure conditions change rapidly, and this movement of acid changes the concentration of acid so that an abnormal pattern may be formed.

FIGS. 1A to 1C are cross-sectional views used to explain chemical flare and correspond to a case of a wafer having a low exposed area ratio (EAR).

Referring to FIG. 1A, a mask 120 with a pattern 130 may be formed on a wafer 100 coated with a photoresist 110.

When light is irradiated onto the mask 120, some parallel light is incident on the surface of the photoresist. Light transmitted through the mask may be of zero order. Light generally does not penetrate the mask pattern 130 coated with chrome, but may penetrate a region not coated with chrome and may be incident on the photoresist 110 disposed on the wafer 100, which may be referred to as exposure.

A sensitizer may be dissolved in the exposed photoresist, and an acid may be formed. A region where the sensitizer is dissolved may have the property of being easily dissolved in a development solution. In addition, Sus theory and Levin theory both offer explanations of the chemical mechanism by which the sensitizer dissolves to form the acid. In essence, the sensitizer may be dissolved when irradiated with light, ketene may be generated, and thus a carboxylic acid and/or a lactonic acid may be formed.

Accordingly, the acid may be formed in a first region 140 on which light is incident, and not formed in a second region 150 on which light is not incident. In addition, as shown in FIG. 1A, the first region 140 may have a small area as compared to the second region 150 on which light is not incident.

Referring to FIG. 1B, a post exposure bake (PEB) process may be performed on the exposure processed wafer 100.

The PEB process may be employed to reduce and/or solve a standing wave problem and improve a profile of patterns. That is, in the PEB process, the sensitizer may diffuse in the over-exposed region and the insufficiently exposed region to cause a sidewall of the pattern to have an almost vertical profile.

However, during such a procedure, the acid may evaporate at an exposed surface of the first region 140 or may diffuse into the adjacent second region 150. That is, the acid formed by the dissolved sensitizer may be consumed at the surface of the first region 140 and thus, may become less concentrated than at a central part of the first region 140.

Referring to FIG. 1C, a development process may be performed on the PEB processed wafer 100.

The development process is a process of removing the exposed first region 140 using a development solution. The development solution is generally alkali, and the exposed photoresist may be removed when the acid formed by the exposure process is removed.

If the acid concentration on the surface of the first region 140 is uneven as illustrated in FIG. 1B, the surface of the first region 140 may not be removed by the development solution while central and lower portions of the first region 140 may be removed by the development solution as illustrated in FIG. 1C.

Accordingly, the patterns formed by the development process may have a “T”-shape in which upper portions extend laterally, for example, in the right and left directions shown in FIG. 1C. This phenomenon generally becomes more severe when the patterns are in close proximity to the second region 150. This may be because a portion of the first region 140 in close proximity to the second region 150 in FIG. 1B generally has a higher acid concentration than the second region 150, and such a concentration gradient may accelerate diffusion and/or evaporation of the acid.

FIGS. 2A to 2C are cross-sectional views for explaining chemical flare and correspond to the case of a wafer 200 having a high EAR.

The description relating to FIGS. 2A to 2C is the same as the description relating to FIGS. 1A to 1C except that the wafer 200 has a high EAR, whereas the wafer 100 shown in FIGS. 1A to 1C has a low EAR. Because the wafer 200 has a high EAR, a different phenomenon may occur.

Referring to FIG. 2A, parallel light may be irradiated onto a mask 220, and the light penetrating regions where mask patterns 230 are not formed may be incident on the wafer 200 coated with a photoresist 210. Sensitizer is generally not dissolved and acid is generally not formed in a region where light is not incident in a first region 240. However, sensitizer generally is dissolved and acid may be formed in a second region 250 where light is incident on the wafer 200. The first region 240 may have a smaller area than the second region 250.

Referring to FIG. 2B, a PEB process may be performed on the exposure processed wafer 200. During the PEB process, the acid formed on the surface of the second region 250 may be diffused into the surface of the first region 240. This is because acid is generally more highly concentrated on the surface of the second region 250 than on the surface of the first region 240, which creates a concentration gradient at a boundary between the first region 240 and the second region 250.

In addition, an amount of diffused acid may increase from the first region 240 to the second region 250.

Referring to FIG. 2C, a development process may be performed on the PEB processed wafer 200.

The exposed photoresist may be removed by an alkali development solution. Accordingly, a plurality of patterns may be formed in the first region 240. However, the patterns may be thinner near the boundary with the second region 250 than in a central region of the first region 240, due to the acid diffusion illustrated in FIG. 2B. Further, the rounding phenomenon at upper portions of the patterns may be more severe when the patterns are in close proximity to the second region 250.

The above-described chemical flare phenomenon may create non-uniform patterns and may inhibit accurate patterns from being formed.

### SUMMARY

An example embodiment of the present invention provides a mask pattern for removing chemical non-uniformity, which could cause chemical flare to occur.

An example embodiment of the present invention provides a method of patterning a photoresist using a mask pattern.

An example embodiment of the present invention provides a mask. The mask may include a first mask region having a plurality of dense patterns and transferring the dense patterns; and a second mask region disposed around the first mask region and having balance patterns with a pitch smaller than that of the patterns of the first mask region. A photoresist may be removed or may remain depending on a duty of the balance patterns.

An example embodiment of the present invention provides a mask. The mask may include a first mask region having a plurality of dense patterns and transferring the dense patterns; and a second mask region having balance patterns regularly arranged around the first mask region. The balance patterns of the second mask region may reduce and/or prevent rapid chemical imbalance from occurring in a photoresist region corresponding to a boundary between the first and second mask regions by means of pitch adjustment.

An example embodiment of the present invention is directed to a method of patterning a photoresist using a mask, including carrying out an exposure process on a wafer on which the photoresist is coated using the mask, the mask having a first mask region with a plurality of dense patterns and a second mask region with balance patterns regularly arranged around the first mask region; and patterning the photoresist of a first wafer region corresponding to the first mask region on the wafer where the exposure is performed, and completely removing the photoresist of a second wafer region corresponding to the second mask region, or making the photoresist of the second wafer region completely remain, wherein the balance patterns prevent rapid chemical imbalance from occurring in a boundary between the first and second wafer regions by means of pitch adjustment.

An example embodiment of the present invention provides a method of patterning a photoresist using a mask. The method may include carrying out an exposure process on a wafer on which the photoresist is coated using the mask, the mask having a first mask region with a plurality of dense patterns and a second mask region with balance patterns regularly arranged around the first mask region; and patterning the photoresist of a first wafer region corresponding to the first mask region on the exposed wafer, wherein the balance patterns inhibit a rapid chemical imbalance from occurring at a boundary between the first and second wafer regions based on a pitch of the balance patterns and the photoresist in the second region remains or is removed based on a duty of the balance patterns.

### BRIEF DESCRIPTION OF THE DRAWINGS

The foregoing and other objects, features and advantages of the invention will be apparent by considering the following detailed description of example embodiments of the present invention in conjunction with the accompanying drawings. The drawings are not necessarily to scale, emphasis instead being placed upon illustrating the principles of the invention.

FIGS. 1A to 1C are cross-sectional views for explaining chemical flare and correspond to a case in which a wafer has a low EAR.

FIGS. 2A to 2C are cross-sectional views for explaining chemical flare and correspond to a case in which a wafer has a high EAR.

FIGS. 3A to 3C are plan views of mask patterns in accordance with an example embodiment of the present invention.

FIGS. 4A and 4B are cross-sectional views for explaining an operation of balance patterns illustrated in FIGS. 3A to 3C in accordance with an example embodiment of the present invention.

FIGS. 5A and 5B are cross-sectional views for explaining an operation of balance patterns illustrated in FIGS. 3A to 3C in accordance with an example embodiment of the present invention.

FIG. 6 is a graph showing the intensity of light irradiated onto a photoresist while changing a duty of balance patterns in accordance with an example embodiment of the present invention.

FIGS. 7A to 7C are plan views of masks in accordance with an example embodiment of the present invention.

FIGS. 8A to 8C are plan views of masks in accordance with an example embodiment of the present invention.

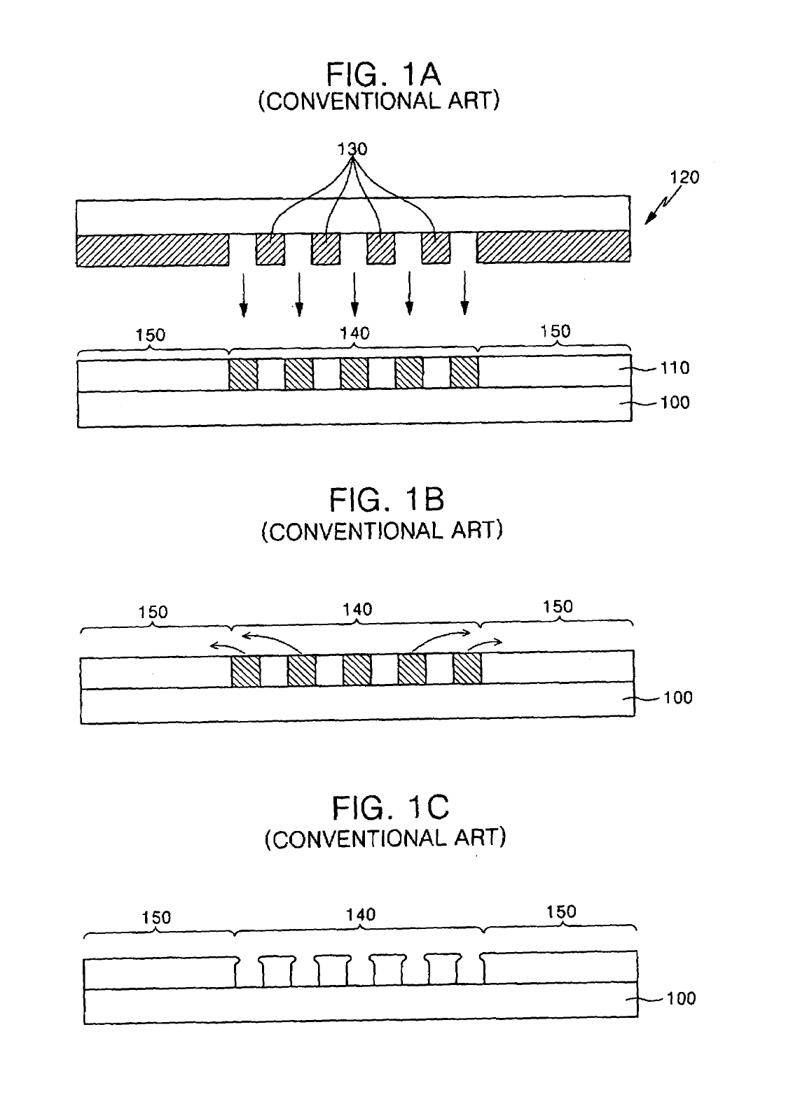

### DETAILED DESCRIPTION OF EXAMPLE EMBODIMENTS OF THE PRESENT INVENTION

Example embodiment of the present invention will now be described more fully hereinafter with reference to the accompanying drawings. This invention may, however, be embodied in different forms and should not be construed as limited to the example embodiments set forth herein. Rather, these example embodiments are provided so that this disclosure will be thorough and complete, and will fully convey the scope of the invention to those skilled in the art. Like reference numbers refer to like components throughout the specification.

It will be understood that, although the terms first, second, etc. may be used herein to describe various components, these components should not be limited by these terms. These terms are only used to distinguish one component from another. For example, a first component could be termed a second component, and, similarly, a second component could be termed a first component, without departing from the scope of the present invention. As used herein, the term “and/or” includes any and all combinations of the one or more of the associated listed items.

It will also be understood that when a component is referred to as being “connected” or “coupled” to another component, it can be directly connected or coupled to the other component or intervening components may be present. In contrast, when a component is referred to as being “directly connected” or “directly coupled” to another component, there are no intervening components present.

The terminology used herein is for the purpose of describing particular embodiments only and is not intended to be limiting of example embodiments of the present invention. As used herein, the singular forms “a”, “an” and “the” are intended to include the plural forms as well, unless the context clearly indicates otherwise. It will be further understood that the terms “comprises”, “comprising”, “includes” and/or “including”, when used herein, specify the presence of stated features, integers, steps, operations, elements, and/or components, but do not preclude the presence or addition of one or more other features, integers, steps, operations, elements, components, and/or groups thereof.

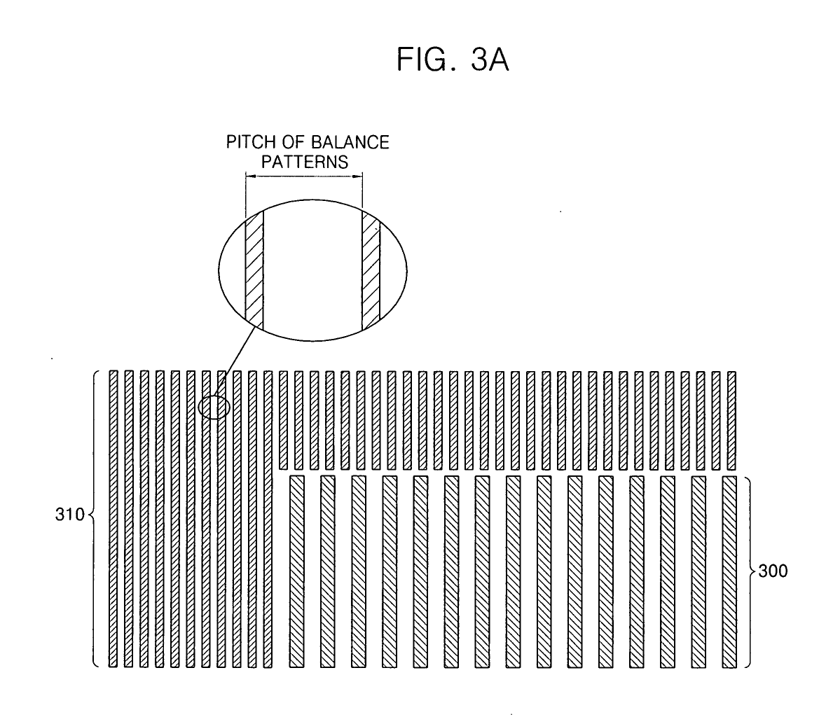

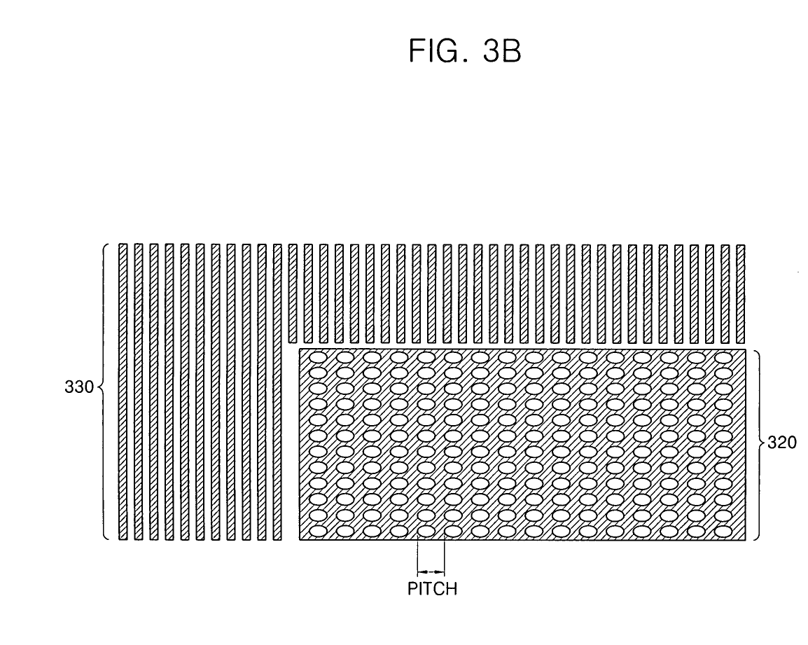

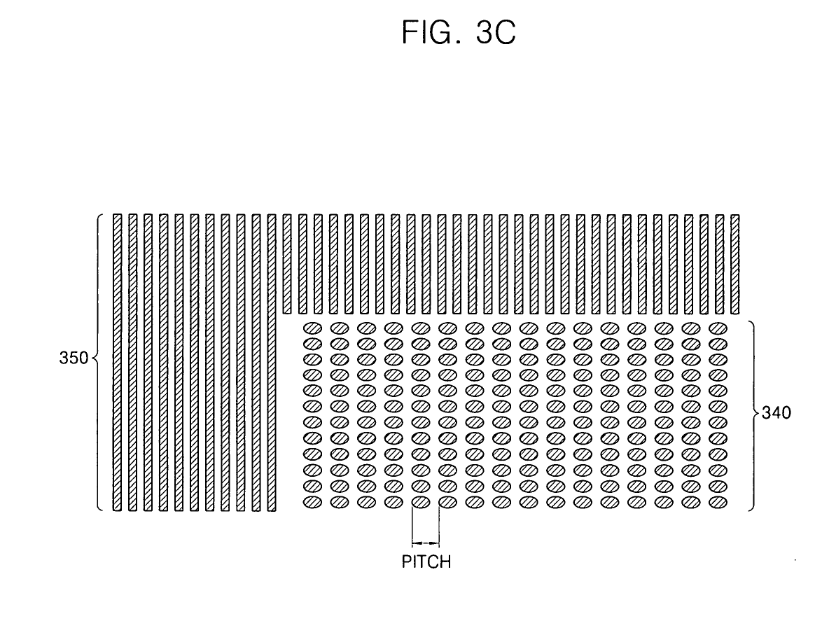

FIGS. 3A to 3C are plan views of mask patterns in accordance with an example embodiment of the present invention.

In the examples shown in FIGS. 3A to 3C, the mask pattern includes a first mask region where relatively dense patterns are formed and a second mask region where balance patterns are formed. A chemical flare phenomenon may be reduced and/or prevented by the balance patterns disposed in the second mask region.

Referring to FIG. 3A, the mask patterns formed on the mask may have a first mask region 300 and a second mask region 310.

The first mask region 300 may include a plurality of line & space type patterns and may be used to transfer the line & space type patterns during fabrication of a semiconductor device. According to the example shown in FIG. 3A, the line & space type patterns are relatively dense in the first mask region 300.

The second mask region 310 may include a plurality of balance patterns. The balance patterns may be a plurality of line & space type patterns.

A pitch between the line patterns in the second mask region 310 may be set smaller than a pitch between the line & space type patterns in the first mask region 300. The configuration of the second mask region 310 may cause a photoresist to remain on the wafer even if light is irradiated thereon. Alternatively, the configuration of the second mask region 310 may cause the photoresist on the wafer to be removed according to the light irradiation.

That is, the photoresist corresponding to the second mask region 310 may remain in the second mask region 310 because of the balance patterns, or may be removed from the second mask region 310 because of the balance patterns, if desired and/or necessary. A result of the balance patterns on the photoresist in the second mask region 310 may be determined by a duty of the balance patterns and the pitch of the balance patterns within the second mask region 310.

If the duty, which indicates a width of the mask pattern relative to the pitch, exceeds a threshold value, the photoresist may remain in response to light transmitted through the balance patterns. Alternatively, if the duty of the balance patterns is less than or equal to the threshold value, the photoresist may be removed in response to light transmitted through the balance patterns.

In addition, if the pitch of the balance patterns disposed in the second mask region 310 exceeds the threshold value, the balance patterns may be transferred onto the photoresist. However, if the pitch is equal to or less than the threshold value, the balance patterns may not be transferred onto the photoresist and instead may be completely removed or completely remain in response to the duty of the balance patterns. The pitch of the balance patterns disposed in the second mask region 310 may be set equal to or less than the threshold value according to an example embodiment of the present invention and thus, the photoresist may be removed or may remain depending on the duty of the balance patterns disposed in the second mask region 310.

Referring to an example shown in FIG. 3B, a first mask region 320 may include relatively dense patterns having a contact structure and a second mask region 330 may include balance patterns having a line & space structure. Light may be transmitted through the contact patterns of the first mask region 320 having the contact structure and irradiated onto the photoresist of the wafer. Accordingly, the photoresist corresponding to the patterns disposed in the first mask region 320 may be patterned.

In addition, the configuration and operation of the balance patterns disposed in the second mask region 330 may cause effects similar to the effects of the balance patterns disposed in the second mask region 310 of FIG. 3A. That is, the mask patterns illustrated in FIG. 3C may cause substantially the same effects as the patterns illustrated in FIG. 3A except that the shape of the patterns disposed in the first region 320 is different. Accordingly, a description of the balance patterns and the effects of the balance patterns disposed in the second mask region 330 will be omitted herein for the sake of brevity.

Referring to the example shown in FIG. 3C, the mask may include a first mask region 340 where relatively dense patterns are disposed and a second mask region 350 where balance patterns are disposed. The first mask region 340 may have a pillar structure, and the second mask region 350 may have a line & space structure. The first mask region 340 having the pillar structure may pattern a photoresist corresponding to the first mask region 340. For example, the first mask region 340 may be a portion where the patterns are to be transferred.

The configuration and operation of the balance patterns disposed in the second mask region 350 may be the same as the balance patterns described with reference to FIG. 3A. That is, the mask patterns illustrated in FIG. 3C may be substantially the same as the patterns illustrated in FIG. 3A except that the shape of the patterns disposed in the first region 340 may be different. Accordingly, a description of the balance patterns disposed in the second mask region 350 will be omitted herein for the sake of brevity.

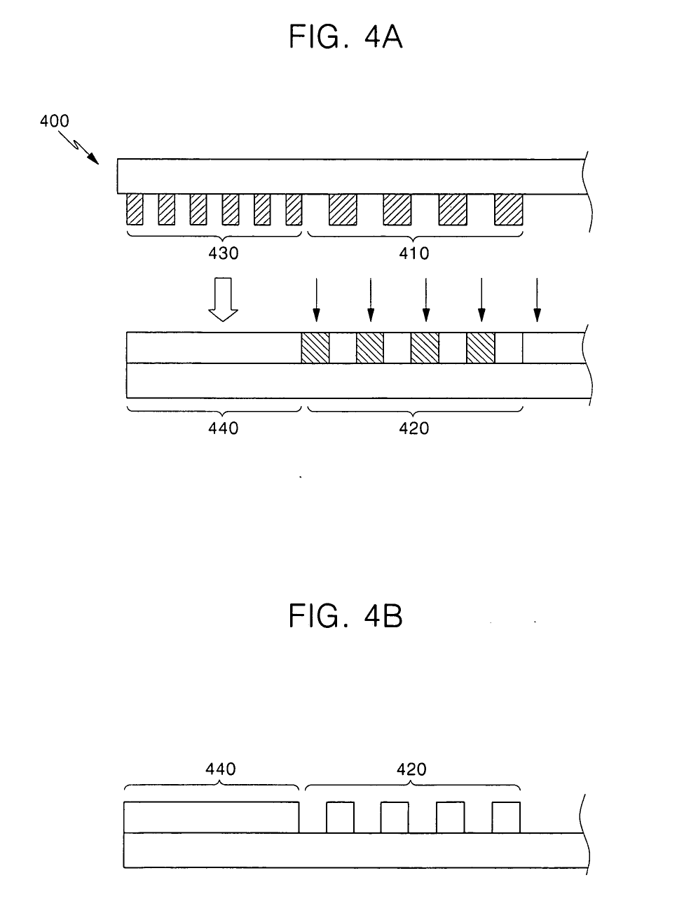

FIGS. 4A and 4B are cross-sectional views for explaining an example operation of balance patterns illustrated in FIGS. 3A to 3C according to an example embodiment of the present invention.

The description relating to FIGS. 4A and 4B describes an example embodiment of the present invention in which the photoresist corresponding to the balance patterns remain even if light is irradiated onto the photoresist.

Referring to FIG. 4A, light may be irradiated onto a mask 400. In the example of FIG. 4A, light transmitted through a first mask region 410 where desired and/or predetermined patterns are disposed may be irradiated onto a first wafer region 420. In addition, the photoresist on the first wafer region 420 corresponding to the first mask region 410 may be exposed to light and a sensitizer may be dissolved in the exposed photoresist so that an acid may be formed.

In addition, line & space balance patterns may be disposed in a second mask region 430 in the example of FIG. 4A. A pitch of the balance patterns may be set such that light transmitted through the second mask region 430 is of zero order. The pitch of the balance patterns may be determined by Equation 1 shown below.

P<λ/NA(1+σ), σ=σ max COS θ min (1)

### In Equation 1, P indicates the pitch of the balance patterns, NA indicates the numerical aperture, λ indicates the wavelength of light, and σ indicates a coherence factor of an exposure device.

According to an example embodiment of the present invention, if the pitch of the balance patterns is set according to Equation 1, light transmitted through the balance patterns becomes light of zero order. In addition, if the pitch of the balance patterns is set by Equation 1, the photoresist of a second wafer region 440 corresponding to the balance patterns may be removed or may remain. Accordingly, the light transmitted through the balance patterns does not transcribe the patterns if the pitch of the balance patterns is set according to Equation 1.

In the example shown in FIG. 4A, the duty of the balance patterns may be set so that the photoresist formed on the second wafer 440 remains.

The light transmitted through the second mask region 430 having line & space type balance patterns may be incident on the photoresist in the second wafer region 440 corresponding to the second mask region 430. However, image contrast may be set to zero by the balance patterns, so that the acid may be formed only on the surface of the photoresist.

A sensitizer may be dissolved in the photoresist formed in the first wafer region 420 by the light transmitted through the first mask region 410 so that an acid may be formed, and a sensitizer may be dissolved on a surface of the photoresist formed in the second wafer region 440 by the light transmitted through the second mask region 430 so that an acid may be formed. That is, the acid may be formed in the first wafer region 420 where the patterns are to be transferred, and may also be formed on the surface of the second wafer region 440 where the balance patterns are not transferred. Accordingly, the chemical flare phenomenon caused by a rapid concentration gradient in the region where the relatively dense patterns are disposed and in the region where patterns are not transferred may be reduced and/or prevented.

Referring to FIG. 4B, the region where the acid is formed by the pattern transfer in the first wafer region 420 may be removed by a development process. According to the example shown in FIG. 4B, the patterns are not transferred in the second wafer region 440, and the second mask pattern 430 is set such that the image contrast becomes zero so that the photoresist of the second wafer region 440 remains.

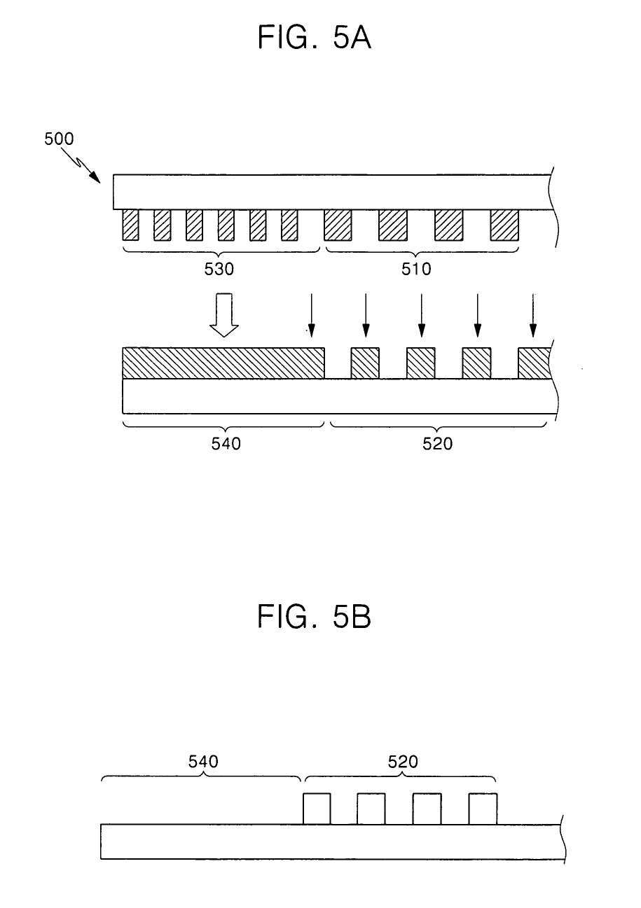

FIGS. 5A and 5B are cross-sectional views for explaining the operation of balance patterns illustrated in FIGS. 3A to 3C according to an example embodiment of the present invention.

FIGS. 5A and 5B show an example embodiment of the present invention in which the photoresist corresponding to the balance patterns is removed by light irradiation.

Referring to FIG. 5A, light may be irradiated onto a mask 500, and the light transmitted through a first mask region 510 where desired and/or predetermined patterns are formed may be irradiated onto a first wafer region 520. In addition, the photoresist on the first wafer region 520 corresponding to the first mask region 510 may be exposed to light, and a sensitizer may be dissolved in the exposed photoresist so that an acid may be formed.

In the example shown in FIG. 5A, the line & space type balance patterns are formed in a second mask region 530. A pitch of the balance patterns may be set so that light transmitted through the second mask region 530 is of zero order. The pitch of the balance patterns may be determined by Equation 1 as previously described.

If the pitch of the balance patterns is set by Equation 1, most light transmitted through the balance patterns becomes of zero order.

In the example shown in FIG. 5A, the duty of the balance patterns may be set so that the photoresist formed in a second wafer region 540 may be removed. That is, the duty of the balance patterns may be set to exceed a threshold value of the light intensity at which the photoresist of the second wafer region 540 may be completely removed.

Light transmitted through spaces of the balance patterns may be incident on the photoresist on the second wafer region 540 corresponding to the second mask region 530. In addition, the incident light may act to dissolve the sensitizer in the photoresist on the second wafer region 540 and may cause an acid to be formed. However, the concentration of acid formed in the photoresist on the second wafer region 540 may be lower than when the balance patterns are not formed in the second mask region 540.

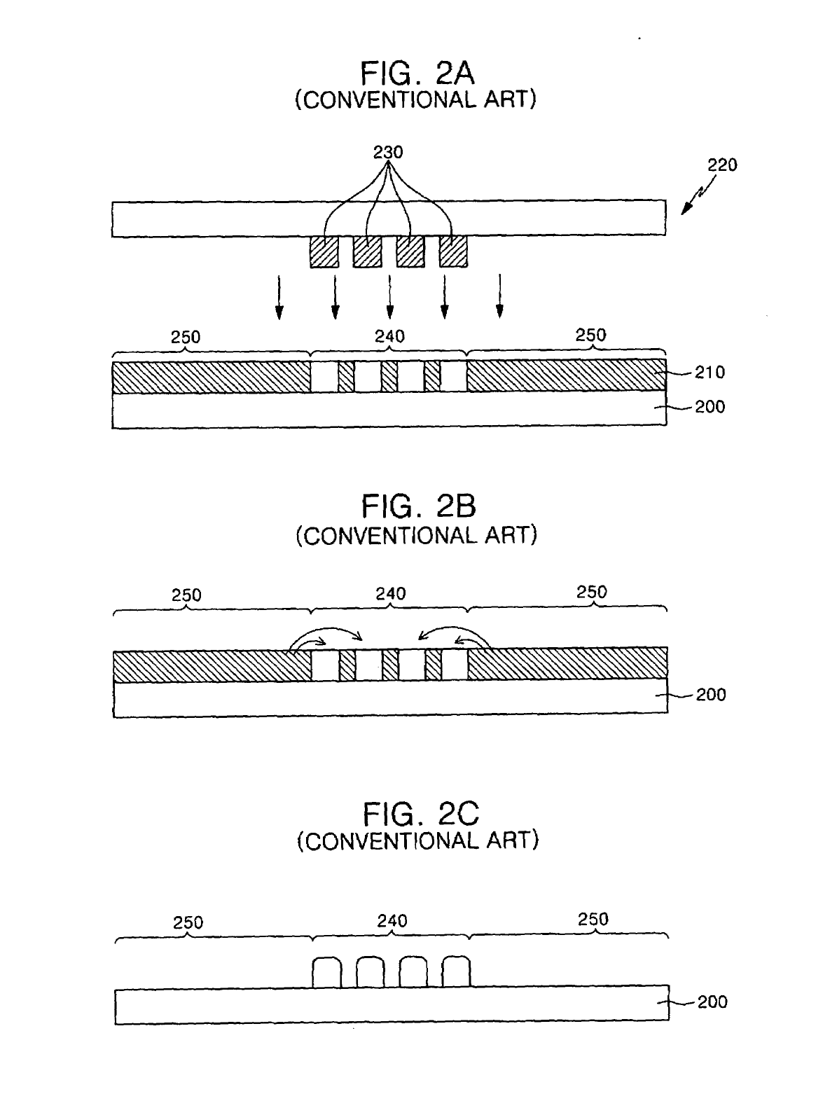

According to an example embodiment of the present invention, the acid concentration gradient may occur in the first wafer region 520 and the second wafer region 540 to some extent after the mask is irradiated with light. However, the acid expansion may not cause the patterns in the first wafer region 520 to be deformed as shown in the conventional method of FIG. 2.

Accordingly, the chemical flare phenomenon due to the rapid concentration gradient of the acid in the region where relatively dense patterns are disposed and in the region where patterns are not transferred, may be reduced and/or prevented.

As shown in the example of FIG. 5B, the region where the acid is formed by the pattern transfer in the first wafer region 420 may be removed by a development process. In addition, the patterns in the second wafer region 540 may be removed by the light irradiation.

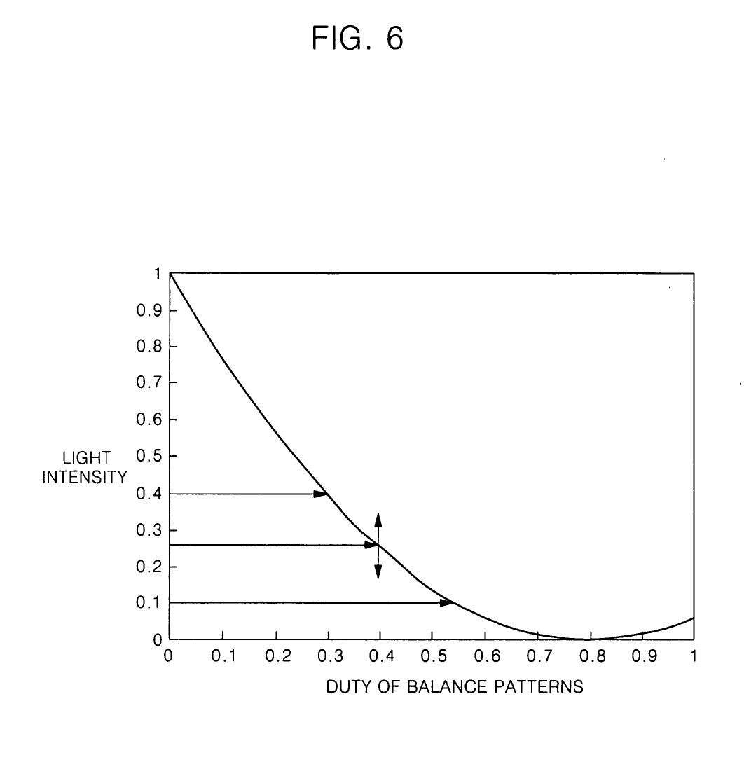

FIG. 6 is a graph showing the intensity of light irradiated onto a photoresist relative to the changing of the duty of balance patterns in accordance with an example embodiment of the present invention. Referring to FIG. 6, the pitch of balance patterns is about 140 nm and the wavelength of the irradiated light is about 193 nm. In addition, the intensity of the light irradiated onto the photoresist is set to 1 when the photoresist is completely removed because there is no pattern in the mask. In addition, a cutting level, which is the intensity of the light at which the light is irradiated onto the photoresist applied in the present example and the photoresist starts to be removed by the development process, is set to a value within a range of about 0.22 to about 0.25. The duty of the balance patterns corresponding to the cutting level is about 0.55.

If the duty of the balance patterns in FIG. 6 maintains a value of about 0.3, the intensity of light irradiated onto the photoresist may be about 0.4, which exceeds the cutting level, so that the photoresist on which light is irradiated may be completely removed. However, the concentration of the acid formed in the photoresist by the light irradiation may be reduced as compared with the intensity of 1. Accordingly, the rapid concentration gradient generally does not occur between the region irradiated by the balance patterns and the region irradiated by the relatively dense patterns. As a result, the chemical flare may be reduced by about 60%.

In addition, if the mask duty maintains a value of about 0.55 in FIG. 6, the intensity of light irradiated onto the photoresist maintains a value of about 0.1, which is be less than the cutting level. Accordingly, the photoresist may not be removed even when the light transmitted through the balance patterns is irradiated thereon. However, the chemical flare due to the imbalance of chemical concentration may be reduced at a boundary region between the region where patterns are formed by the irradiation of light having a desired and/or predetermined intensity and the photoresist region to be masked.

If the wavelength of the light used in the example is high, the pitch of the balance patterns should also be set high. That is, when the balance patterns for reducing and/or preventing the chemical flare are employed according to example embodiments of the present invention, the pitch of the balance patterns should be set to be in proportion to the wavelength of the light used.

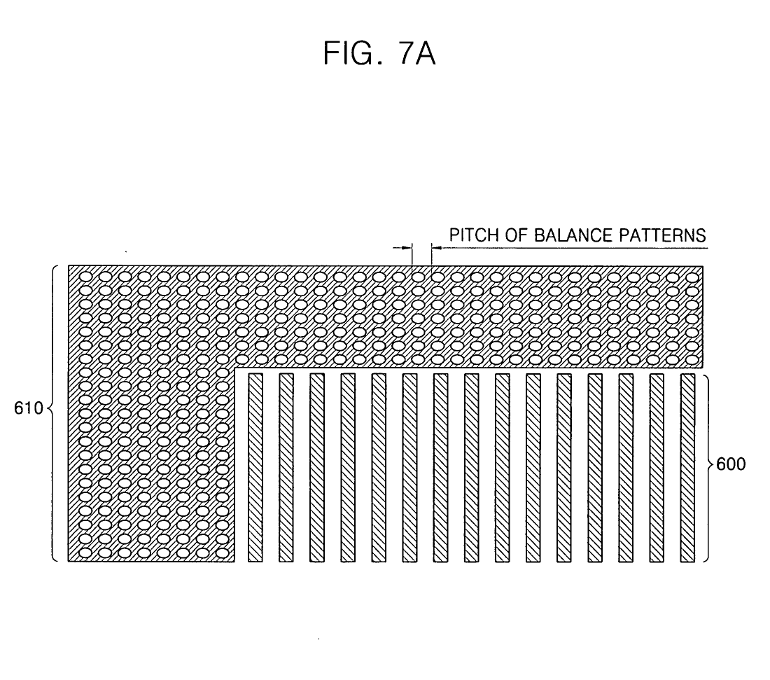

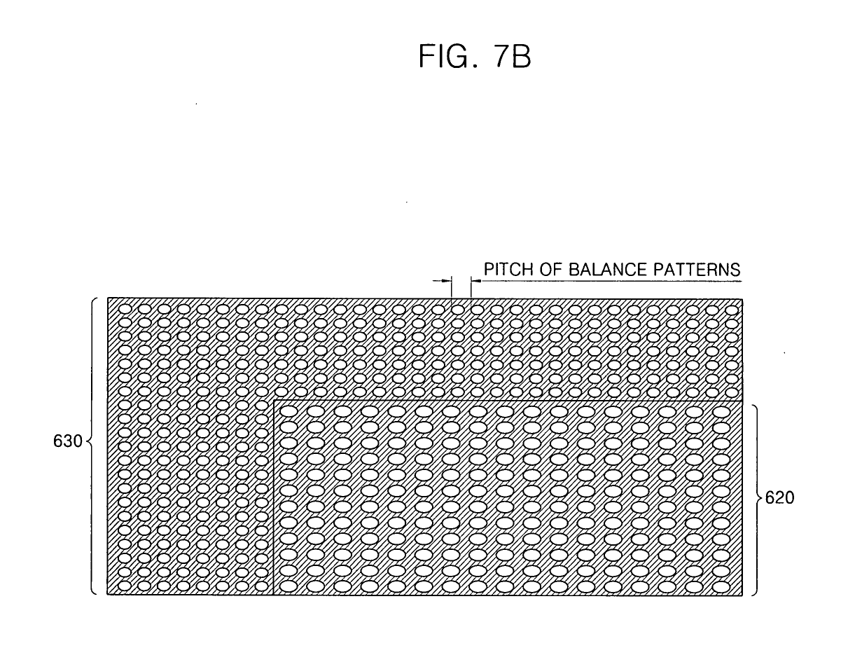

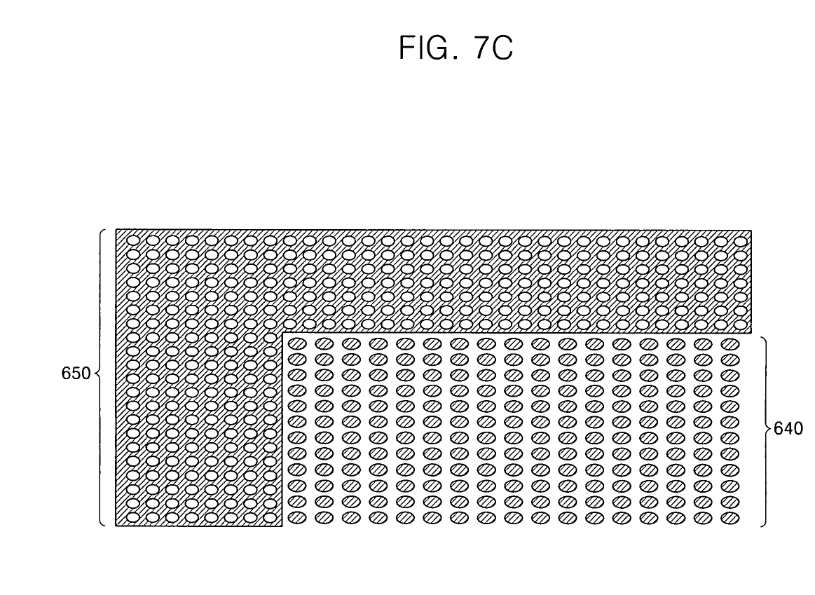

FIGS. 7A to 7C are plan views of masks in accordance with an example embodiment of the present invention.

Referring to FIG. 7A, the mask may include a first mask region 600 and a second mask region 610.

The first mask region 600 may have line & space type patterns, which may be transferred by an exposure process.

In addition, the second mask region 610 may have balance patterns. The balance patterns may have contact structures. That is, contact patterns where light may be transmitted may be regularly arranged at a relatively constant interval. In addition, a pitch of the contact patterns may be set smaller than the pitch of the line & space type patterns disposed in the first mask region 600. The pitch between contacts of the second mask region 610 may be determined based on Equation 1 as previously described.

In addition, a photoresist of the wafer corresponding to the second mask region 610 may be removed from the wafer or may remain on the wafer depending on the duty of the balance patterns.

For example, if the duty of the balance patterns of the second mask region 610 exceeds a duty corresponding to a cutting level, the photoresist corresponding to the second mask region 610 may remain even when an exposure process is performed thereon. However, chemical imbalance between the photoresist to be transferred by the first mask region 600 and a top surface of the photoresist may be reduced and/or removed by the light that has transmitted the balance patterns and thus, a chemical flare phenomenon may be reduced and/or prevented.

Conversely, if the duty of the balance patterns of the second mask region 610 is equal to or less than the duty corresponding to the cutting level, the photoresist corresponding to the second mask region 610 may completely removed by an exposure process. However, the photoresist may have a relatively a low acid concentration because of the light transmitted through the balance patterns as compared to the case when there are no balance patterns and thus, a rapid concentration gradient may be reduced and/or removed at a boundary between the photoresist region corresponding to the first mask region 600 and the photoresist region corresponding to the second mask region 610. Accordingly, the chemical flare due to the rapid concentration gradient may be reduced and/or prevented.

Referring to FIG. 7B, the mask may include a first mask region 620 and a second mask region 630.

The first mask region 620 may have contact patterns, which may be transferred by an exposure process.

In addition, the second mask region 630 may have balance patterns. The balance patterns may have contact structures. That is, the contact patterns where light is transmitted may be regularly arranged in a relatively constant interval. In addition, a pitch of the contact patterns in the second mask region 630 may be set smaller than the pitch of the contact patterns disposed in the first mask region 620. The pitch between contacts of the second mask region 630 may be determined depending on Equation 1 as previously described.

In addition, a photoresist of the wafer corresponding to the second mask region 630 may be removed or may remain depending on the duty of the balance patterns.

Referring to FIG. 7C, the mask may include a first mask region 640 and a second mask region 650.

The first mask region 640 may have pillar patterns, which may be transferred by an exposure process.

In addition, the second mask region 650 may have balance patterns. The shape and operation of the balance patterns disposed in the second mask region 650 in FIG. 7C are substantially the same as those described with reference to FIGS. 7A and 7B. Accordingly, a detailed description of the balance patterns disposed in the second mask region 650 will be omitted for the sake of brevity.

The balance patterns of the second mask region are illustrated as circular contact shapes in FIG. 7C, however, the balance patterns may have various shapes. That is, various patterns other than the line pattern may be applied according to an example embodiment of the present invention.

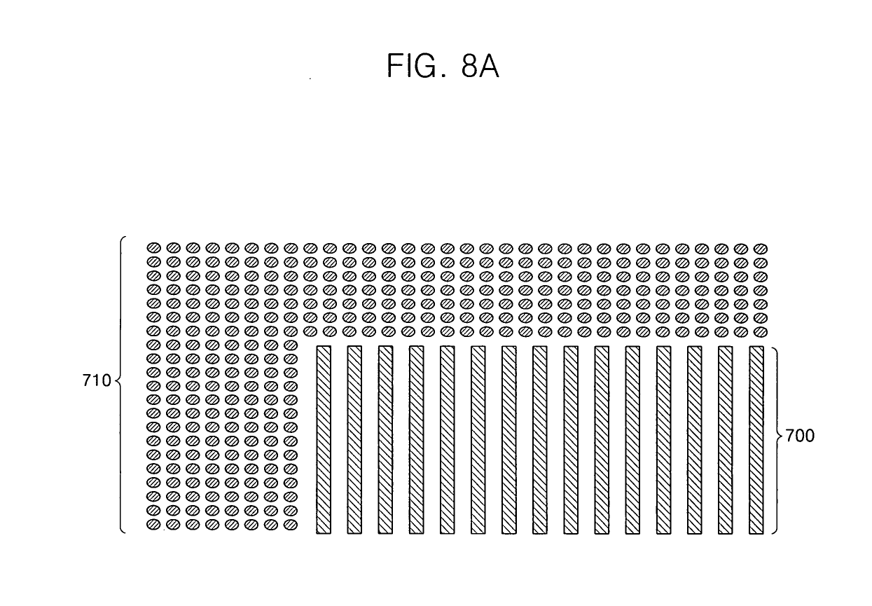

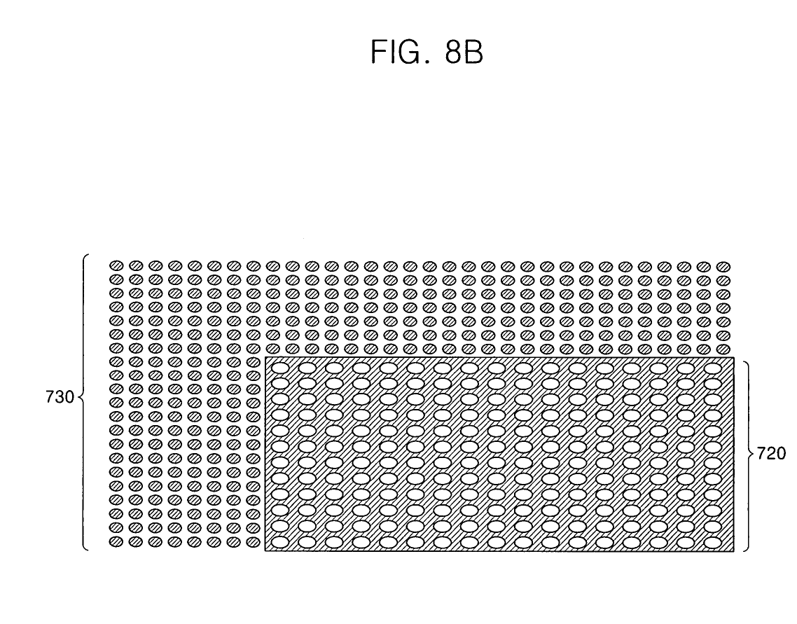

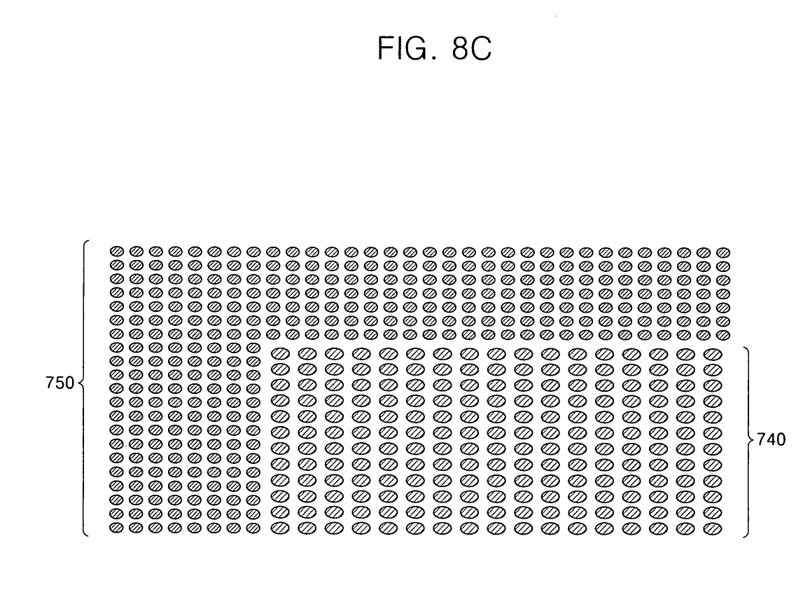

FIGS. 8A to 8C are plan views of masks in accordance with an example embodiment of the present invention. A second mask region where balance patterns are formed may have a pillar shape, and the balance patterns may be regularly arranged in a substantially constant interval. In addition, a pitch between the pillar shape patterns disposed in the second mask region may be determined depending on Equation 1 as previously described.

Referring to FIG. 8A, the mask may include a first mask region 700 where patterns are transferred to a wafer and a second mask region 710 having balance patterns.

The first mask region 700 may have line & space type patterns, and the second mask region 710 having the balance patterns may be composed of a plurality of pillar patterns.

In particular, the second mask region 710 may have a structure where the pillar patterns allowing light to be transmitted are regularly arranged in a substantially constant interval. In addition, a pitch of the pillar patterns may be set smaller than that of the pitch of the line & space type patterns disposed in the first mask region 700. The pitch between pillar patterns of the second mask region 710 may be determined according to Equation 1 as previously described.

In addition, a photoresist of the wafer corresponding to the second mask region 710 may be removed or may remain depending on the duty of the balance patterns.

For example, if the duty of the balance patterns of the second mask region 710 exceeds a duty corresponding to a cutting level, the photoresist corresponding to the second mask region 710 remains even when an exposure process is performed thereon. In addition, chemical imbalance between the photoresist to be transferred by the first mask region 700 and a top surface of the photoresist may be removed by the light that has transmitted the pillar balance patterns, so that a chemical flare phenomenon may be reduced and/or prevented.

Conversely, if the duty of the balance patterns of the second mask region 710 is equal to or less than the duty corresponding to the cutting level, the photoresist corresponding to the second mask region 710 is removed by an exposure process. However, the photoresist has a relatively low acid concentration because of the light that has transmitted the pillar balance patterns as compared to a case where there are no balance patterns and thus, a rapid concentration gradient may be reduced and/or removed at a boundary between the photoresist region corresponding to the first mask region 700 and the photoresist region corresponding to the second mask region 710. Accordingly, the chemical flare due to a rapid concentration gradient may be reduced and/or prevented.

Referring to FIG. 8B, the mask may include a first mask region 720 and a second mask region 730.

The configuration and the operation of the second mask region 730 illustrated in FIG. 8B are substantially the same as those illustrated in FIG. 8A except that patterns disposed in the first mask region 720 may be have differently shaped patterns, for example, contact patterns.

In addition, referring to FIG. 8C, the mask may include a first mask region 740 and a second mask region 750.

The configuration and the operation of the second mask region 750 illustrated in FIG. 8C are the same as shown in FIG. 8A except that the first mask region 740 may include different patterns, for example, pillar patterns. Accordingly, a description of the balance patterns disposed in the second mask region 750 will be omitted herein for the sake of brevity.

In accordance with example embodiments of the present invention, the chemical flare due to the rapid chemical concentration imbalance may be reduced and/or prevented at a boundary between the region where relatively dense patterns are transferred and the region where patterns are not transferred.

According to example embodiments of the present invention as described above, balance patterns for removing chemical imbalance may be disposed around a region where relatively dense patterns are arranged. The balance patterns may have a desired and/or predetermined pitch that causes the patterns to not be transferred onto a photoresist even when light is irradiated thereon. In addition, the photoresist in a region corresponding to the balance patterns may be removed or may remain depending on a duty of the balance patterns. If the photoresist is completely removed or completely remains, a chemical flare phenomenon due to a rapid acid concentration gradient between the region where relatively dense patterns are transferred and the region where patterns are not transferred may be reduced and/or prevented. Accordingly, profile characteristics of the photoresist patterned in the region where patterns are transferred may be improved.

Example embodiments of the present invention have been disclosed herein and, although specific terms are employed, they are meant to be interpreted in a generic and descriptive sense only and not for the purpose of limitation. Accordingly, it will be understood by those of ordinary skill in the art that various changes in form and details may be made to the example embodiments without departing from the spirit and scope of the present invention as set forth in the following claims.

What is claimed is:

1. A mask comprising:
a first mask region having a plurality of dense patterns and transferring the dense patterns; and
a second mask region disposed around the first mask region and having balance patterns with a pitch smaller than a pitch of the plurality of dense patterns of the first mask region and a duty determining if a photoresist is removed or remains.

2. The mask according to claim 1, wherein the balance patterns are arranged with a pitch equal to or smaller than a first threshold value, and the first threshold value corresponds to the following equation:
$$\frac{λ}{NA ( 1 + σ )} , σ = σ max COS θ min ,$$
where NA indicates a numerical aperture, λ indicates a light wavelength, and σ indicates a coherence factor of an exposure device.

3. The mask according to claim 2, wherein
if the duty of the balance patterns is equal to or smaller than a second threshold value, the photoresist is removed; and
if the duty of the balance patterns exceeds the second threshold value, the photoresist remains.

4. The mask according to claim 3, wherein the second threshold value is a duty value corresponding to a cutting level of light intensity at which the photoresist starts to be removed by exposure.

5. The mask according to claim 1, wherein the balance patterns are line & space type.

6. The mask according to claim 1, wherein the balance patterns have contact shapes.

7. The mask according to claim 1, wherein the balance patterns have pillar shapes.

8. A mask comprising:
a first mask region having a plurality of dense patterns and transferring the dense patterns; and
a second mask region having balance patterns arranged around the first mask region with a pitch adjusted to inhibit a rapid chemical imbalance from occurring in a photoresist region between the first mask region and the second mask region.

9. The mask according to claim 8, wherein the pitch of the balance patterns corresponds to the following equation:
$$\frac{λ}{NA ( 1 + σ )} , σ = σ max COS θ min ,$$
where NA indicates a numerical aperture, λ indicates a light wavelength, and σ indicates a coherence factor of an exposure device.

10. The mask according to claim 9, wherein the balance patterns have a duty adjusted to remove or leave behind the photoresist corresponding to the second mask region.

11. The mask according to claim 10, wherein
if the duty of the balance patterns is equal to or smaller than a threshold value, the photoresist is removed; and
if the duty of the balance patterns exceeds the threshold value, the photoresist remains.

12. The mask according to claim 11, wherein the threshold value is a duty value corresponding to a cutting level that is light intensity at which the photoresist starts to be removed by exposure.

13. The mask according to claim 8, wherein the balance patterns are line & space type.

14. The mask according to claim 8, wherein the balance patterns have contact shapes.

15. The mask according to claim 8, wherein the balance patterns have pillar shapes.

16. A method of patterning a photoresist using a mask, comprising:
carrying out an exposure process on a wafer on which the photoresist is coated using the mask, the mask having a first mask region with a plurality of dense patterns and a second mask region with balance patterns regularly arranged around the first mask region; and
patterning the photoresist of a first wafer region corresponding to the first mask region on the exposed wafer,
wherein the balance patterns inhibit a rapid chemical imbalance from occurring at a boundary between the first and second wafer regions based on a pitch of the balance patterns and the photoresist in the second region remains or is removed based on a duty of the balance patterns.

17. The method according to claim 16, further comprising:
setting the pitch of the balance patterns according to the following equation:
$$\frac{λ}{NA ( 1 + σ )} , σ = σ max COS θ min ,$$
where NA indicates a numerical aperture, λ indicates a light wavelength, and σ indicates a coherence factor of an exposure device.

18. The method according to claim 17, further comprising:
adjusting a duty of the balance patterns to control if the photoresist in the second region is completely removed or remains.

19. The method according to claim 18, further comprising:
removing the photoresist in the second region if a duty of the balance patterns is equal to or smaller than a threshold value; and
leaving behind the photoresist in the second region if the duty of the balance patters is greater than the threshold value.

20. The method according to claim 19, wherein the threshold value is a duty value corresponding to a cutting level that is light intensity from which the photoresist starts to be removed by exposure.
